(19) United States
(12) Patent Application Publication
(10) Pub. No.: US 2006/0199393 A1
(43) Pub. Date: Sep. 7, 2006

(54) H20 PLASMA AND H20 VAPOR METHODS FOR RELEASING CHARGES

(75) Inventors: Yuan-Bang Lee, Miaoli County (TW); Tzu-Yang Wu, Hsinchu (TW); Sheng-Liang Pan, Hsin-Chu (TW); U. H. Lin, Taipei City (TW); Yu-Chih Lai, Jhubie City (TW); De-Fang Chen, Taoyuan County (TW); Pei-Hsuan Lin, Sanchong City (TW); Shan-Hua Wu, Hsinchu County (TW); Hung-Hsin Liu, Hsinchu City (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Co., Ltd., Hsin-Chu (TW)

(21) Appl. No.: 11/383,931

(22) Filed: May 17, 2006

Related U.S. Application Data
(63) Continuation-in-part of application No. 11/140,115, filed on May 27, 2005.
(60) Provisional application No. 60/583,719, filed on Jun. 29, 2004.

(51) Int. Cl. H01L 21/302

(52) U.S. Cl. 438/710; 438/972

(57) ABSTRACT

An in-situ performed method utilizing a pure H₂O plasma to remove a layer of resist from a substrate or wafer without substantially accumulating charges thereon. Also, in-situ performed methods utilizing a pure H₂O plasma or a pure H₂O vapor to release or remove charges from a surface or surfaces of a substrate or wafer that have accumulated during one or more IC fabrication processes.

### RELATED APPLICATIONS

This application is a continuation-in-part of U.S. application Ser. No. 11/140,115 filed on May 27, 2005, which claims the benefit of U.S. Provisional Application 60/583,719, filed Jun. 29, 2004. The entire disclosures of U.S. application Ser. Nos. 11/140,115 and 60/583,719 are incorporated herein by reference.

### FIELD OF THE INVENTION

The present invention relates to semiconductor device fabrication. More particularly, the present invention relates to methods for releasing charges from wafers.

### BACKGROUND OF THE INVENTION

Integrated circuits (ICs) are well known in the art and typically comprise an entire electronic circuit fabricated on a single wafer. The ICs are fabricated using many different processes including oxidation, photolithography, etching, ion implantation, and metallization. During these processes, electrical charges accumulate on the surfaces of the wafer, which can reduce gate and/or dielectric oxide quality and/or alter device parameters.

For instance, a photolithographically defined resist pattern layer may be used as a mask for etching an underlying layer of a wafer. After etching, the resist layer, which may be a photoresist or e-beam resist, is usually removed in an oxygen plasma process. In this process, the wafer is positioned in a resist strip process chamber and an etch gas recipe, which includes as its main species oxygen (O₂), is then fed into the chamber. The O₂ etch gas may further include other species, such as H₂O vapor and/or a small amount of N₂. A plasma of the gas ions, which consists substantially of O₂, is formed above the wafer and removes the resist layer.

As schematically depicted in FIG. 1, there is a high tendency during the O₂ plasma-based resist removal process for O₂ radicals to capture electrons within the plasma because of their electronegative characteristics. This leads to relatively low electron density which causes spatially non-uniform distribution of the O₂ plasma. The spatially non-uniform O₂ plasma, in turn, may evoke a charge build-up on the wafer. The charge accumulation on the wafer may cause certain defects including, without limitation, pad pitting, galvanic metal corrosion, tungsten dredging, poor quality gate oxides and the like.

One common prior art method for releasing charges that have accumulated on a wafer during an IC fabrication process, is to perform an in-situ water baking process on the wafer. This method, however, often fails to completely release all the charges from the wafer.

Accordingly, an improved method is needed for substantially eliminating or releasing charges from wafers that accumulate during IC manufacturing.

### SUMMARY

Disclosed herein is an in-situ method of removing electrical charges accumulated on a substrate or wafer during semiconductor IC processing. In one embodiment, the method comprises placing or leaving the substrate or wafer in a process chamber and generating a water plasma in the chamber.

In another embodiment, the method comprises placing or leaving the substrate or wafer in a process chamber and introducing a water vapor into the chamber.

### BRIEF DESCRIPTION OF THE DRAWINGS

FIG. 1 is a drawing schematically depicting wafer surface charge accumulation cause by a prior art O₂ plasma-based resist removal method.

FIG. 2 depicts an exemplary plasma process chamber as used for performing a pure H₂O plasma method for removing a layer of resist from a substrate or wafer without substantially accumulating charges thereon.

FIG. 3 is a flowchart showing the steps of an embodiment of the pure H₂O plasma method for removing a layer of resist from a substrate or wafer without substantially accumulating charges thereon.

FIG. 4 schematically depicts wafer surface charge releasing affected by the pure H₂O plasma-based resist removal method.

FIGS. 5A and 5B are surface charging maps of wafers after resist strip processing using a prior art O₂ plasma method.

FIG. 5C is a surface charging map of a wafer after resist strip processing using the pure H₂O plasma method.

FIGS. 6A and 6B are OM (optical microscope) photographs of metal pads formed on a wafer after resist strip processing using a prior art O₂ plasma method.

FIGS. 7A and 7B are OM photographs of metal pads formed on a wafer after resist strip processing using the pure H₂O plasma method.

FIG. 8A schematically depicts a prior art process flow that utilizes a supplemental H₂O baking process to address tungsten dredge problems.

FIG. 8B schematically depicts an exemplary process flow that utilizes the pure H₂O plasma resist stripping method to solve tungsten dredge problems.

FIG. 9A is a typical surface charging map of a wafer before de-charging.

FIG. 9B is a surface charging map of a wafer after performing a supplemental prior art in-situ H₂O baking process on the wafer.

FIG. 9C is a surface charging map of a wafer after performing the pure H₂O plasma de-charging process on the wafer.

FIG. 10 depicts the plasma process chamber of FIG. 2 as used for performing a pure H₂O plasma method for releasing or removing charges from a surface or surfaces of a substrate or wafer.

FIG. 11 is a flowchart showing the steps of an embodiment of the pure H₂O plasma method for releasing or removing charges from a surface or surfaces of a substrate or wafer.

FIG. 12A is a surface charging map of a wafer after performing a scrubbing cleaning process on the wafer.

FIG. 12B is a surface charging map of the wafer of FIG. 12A after performing the pure H₂O plasma charge removal method.

FIG. 13A is a surface charging map of a wafer after performing a film deposition process on the wafer.

FIG. 13B is a surface charging map of the wafer of FIG. 13A after performing the pure H₂O plasma charge removal method.

FIG. 14 depicts the plasma process chamber of FIG. 2 as used for performing a pure H₂O vapor method for releasing or removing charges from a surface or surfaces of a substrate or wafer.

FIG. 15 is a flowchart showing the steps of an embodiment of the pure H₂O vapor method for releasing or removing charges from a surface or surfaces of a substrate or wafer.

FIG. 16A is a surface charging map of a wafer after performing a photo development process on the wafer.

FIG. 16B is a surface charging map of the wafer of FIG. 16A after performing the pure H₂O vapor charge removal method.

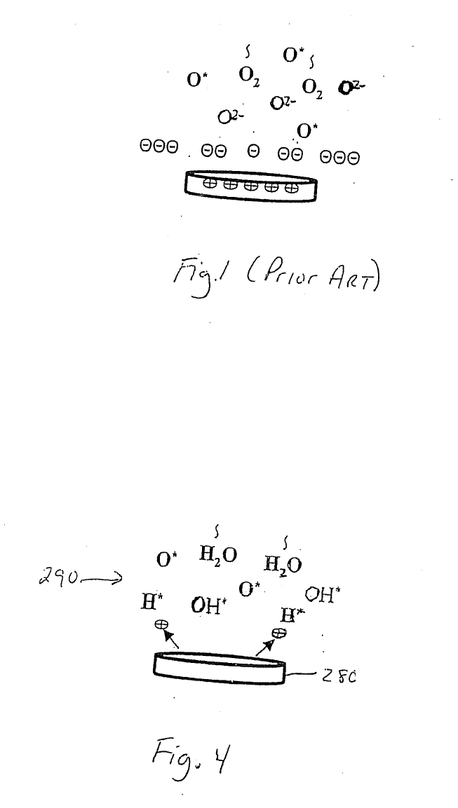

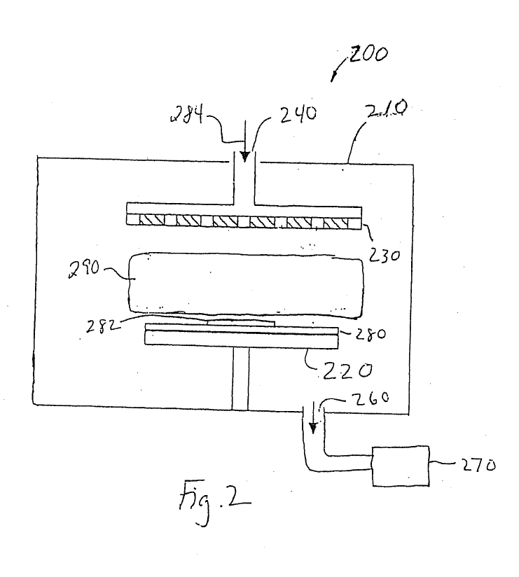

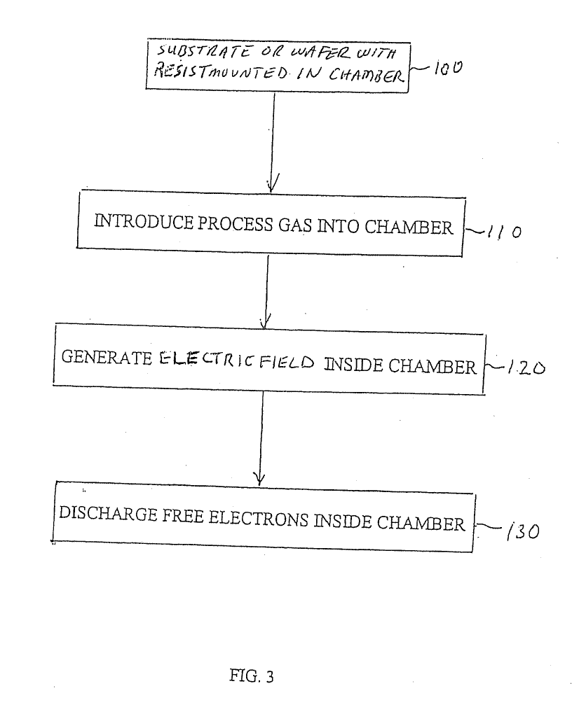

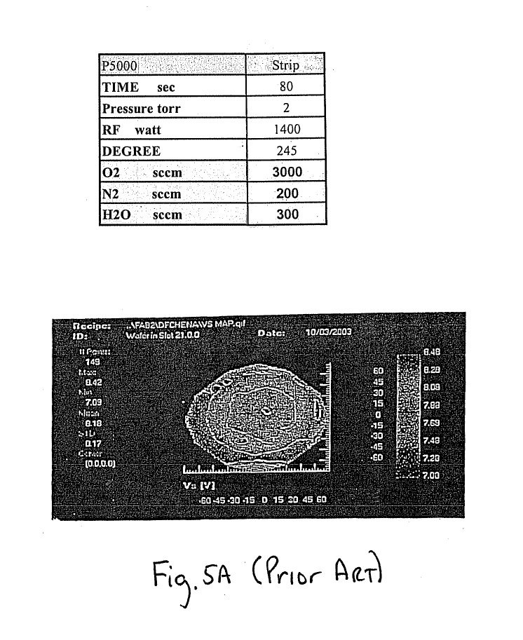

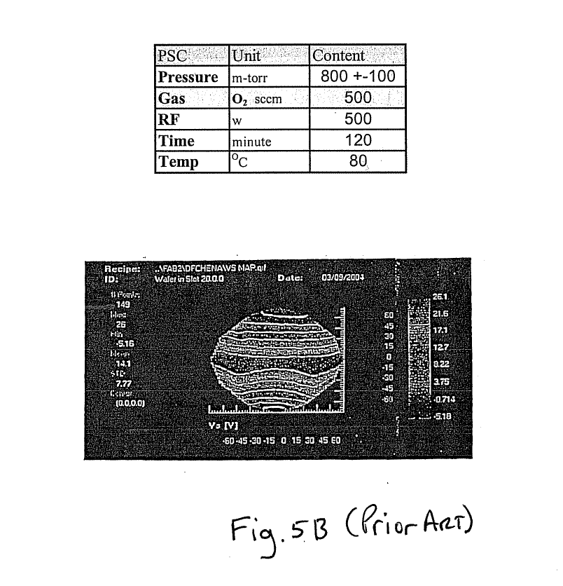

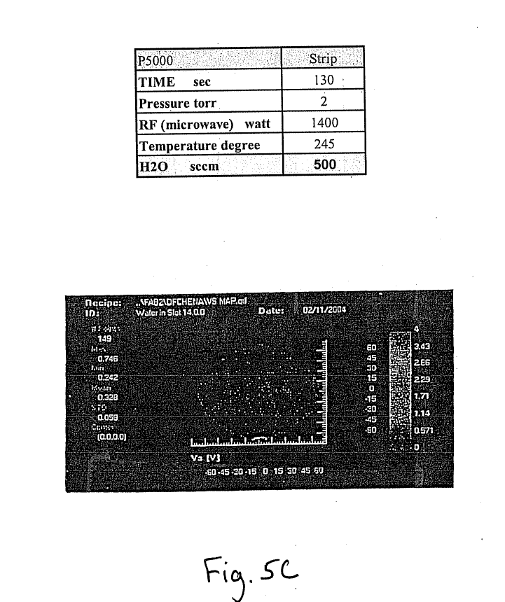

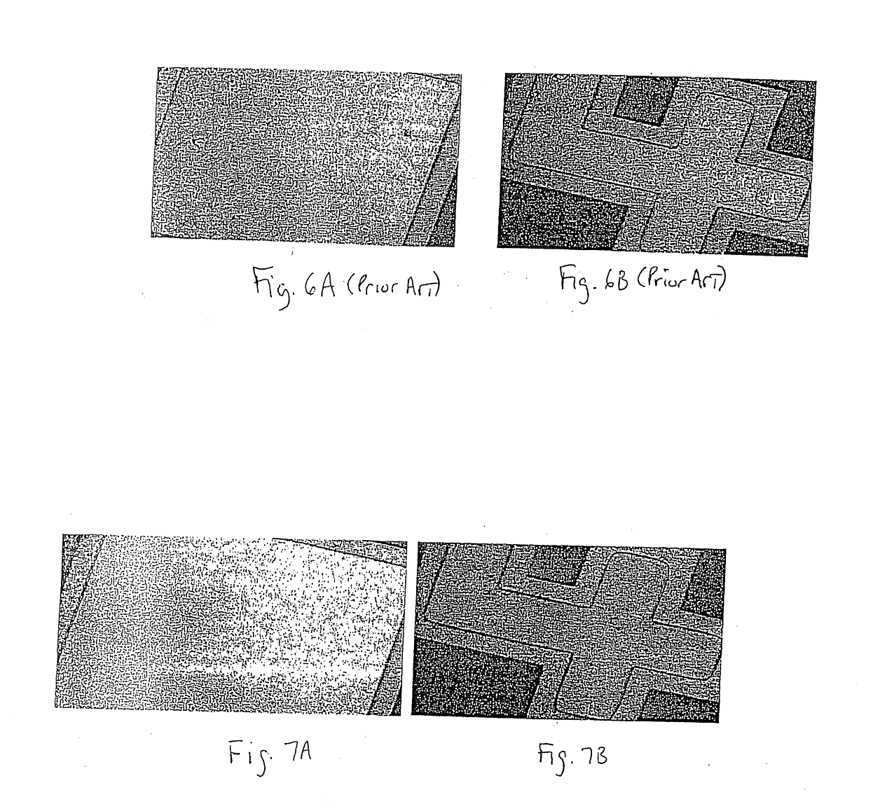

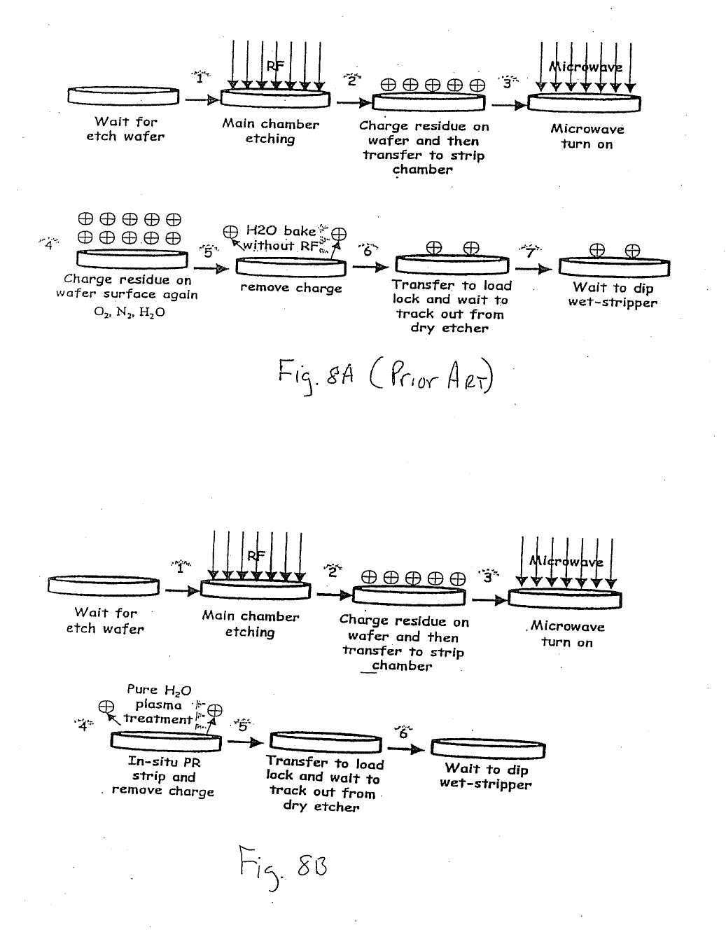

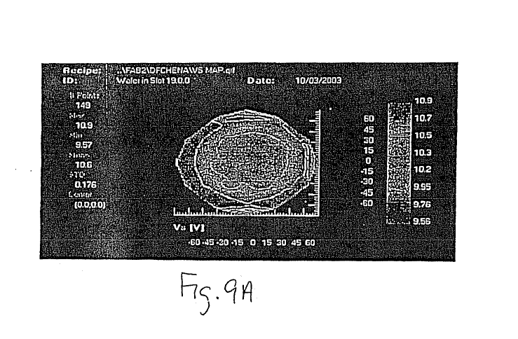

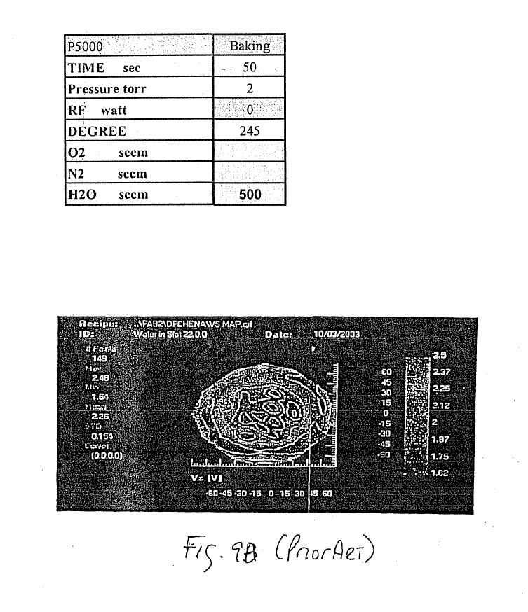

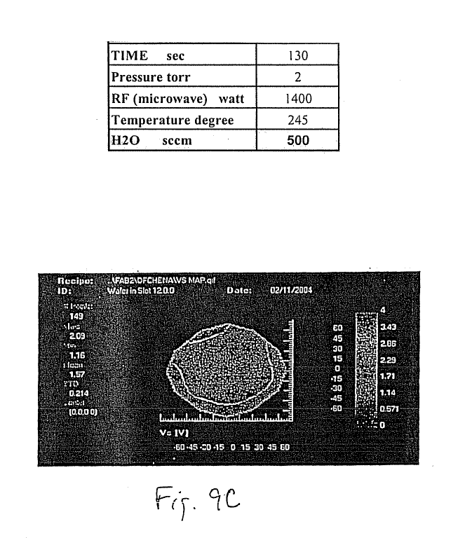

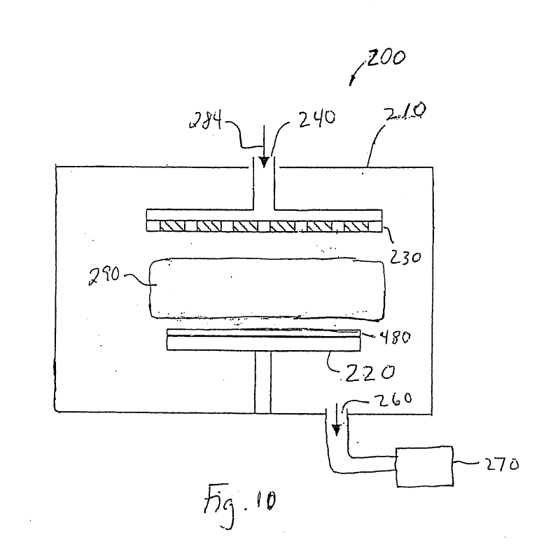

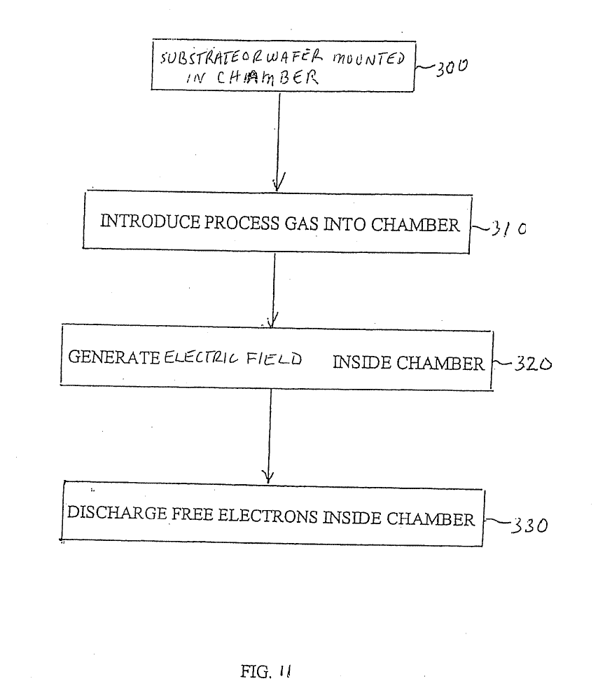

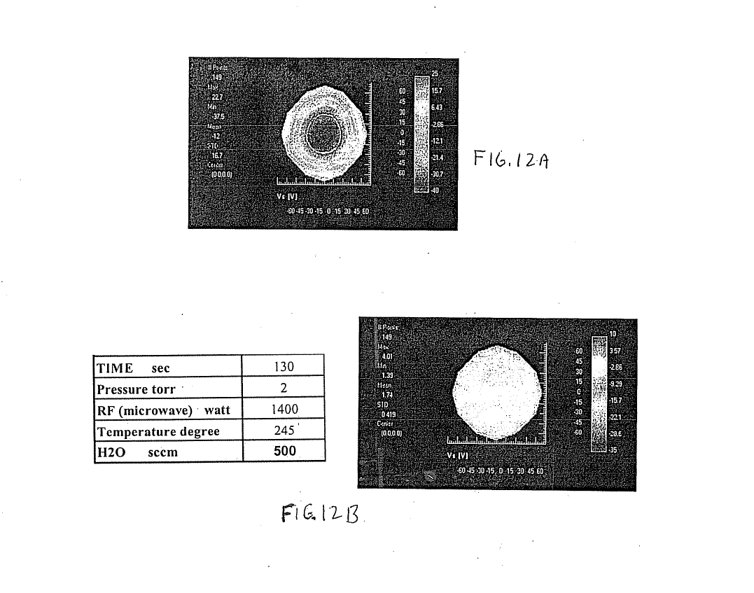

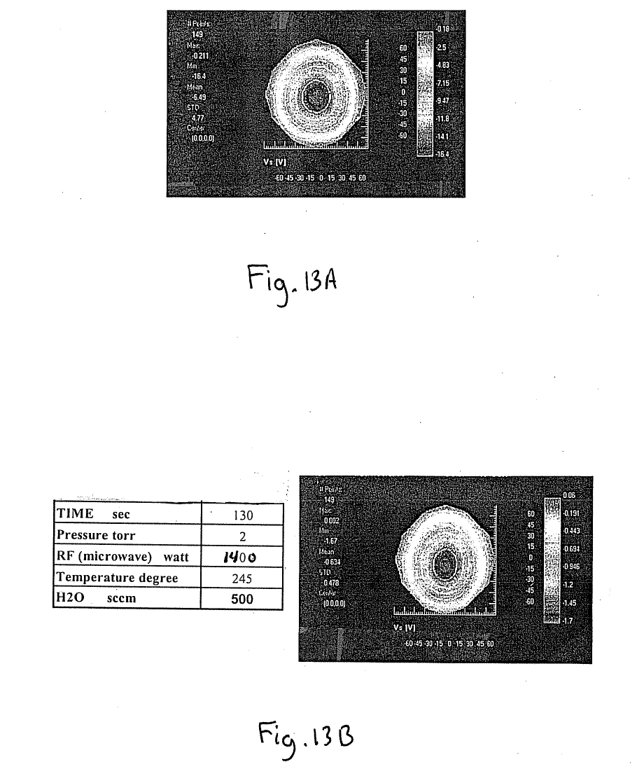

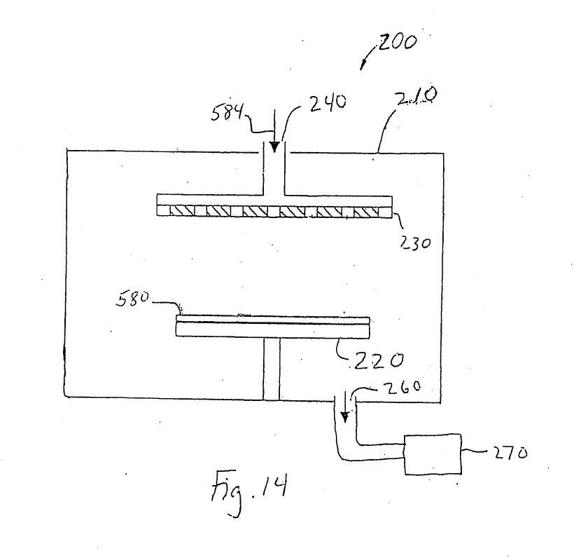

### DETAILED DESCRIPTION

In-situ performed methods are disclosed herein for removing a layer of resist from a substrate or wafer without substantially accumulating charges thereon and/or releasing or removing charges from a surface or surfaces of a substrate or wafer that have accumulated during one or more IC fabrication processes. The methods eliminate or substantially reduce charge enhanced electrochemical problems such as, pad pitting, galvanic metal corrosion, tungsten dredging, poor quality gate oxides and other known electro-chemical problems.

The methods may be performed in a plasma process chamber, such as a conventional resist strip chamber, a plasma etch reactor, or other suitable plasma process chamber. FIG. 2 schematically depicts an exemplary plasma process chamber 200 that may used in the methods. The plasma process chamber includes a housing 210 that defines the plasma process chamber 200. A wafer platform 220 is provided inside the chamber 200. The substrate or wafer to be processed is mounted on the wafer platform 220. A showerhead-shape gas inlet nozzle 230 is disposed above the wafer platform 220. Reaction gases are routed into the chamber 200 via a gas inlet 240, which communicates with the inlet nozzle 230. An exhaust outlet 260 connected to a vacuum pump 270 is used to evacuate the process chamber 200. Electric field generating means (not shown) are used to generate an electric field in the chamber 200 of a sufficient magnitude such that a process fluid flowing in the chamber 200, breaks down and becomes ionized. A plasma may be initiated by releasing or discharging free electrons inside the chamber 200 using, for example, field emission from a negatively biased electrode within the chamber 200.

In one embodiment, a pure H₂O plasma method may be used to remove a layer of resist from a substrate or wafer without substantially accumulating charges (e.g. positive charges) on the substrate or wafer. Referring to FIG. 2 and the flowchart of FIG. 3, the pure H₂O plasma method commences in step 100 with a substrate or wafer 280 mounted on the wafer platform 220 inside the plasma process chamber 200. The substrate or wafer 280 may be composed of a semiconductor material, such as silicon. The substrate or wafer 280 may include one or more layers of resist 282 formed thereon. The resist layer(s) 282 may comprise, for example, a photoresist or an e-beam resist. The resist layer(s) 282 may be at least partially disposed on a metal layer of the substrate or wafer 280 or at least partially disposed on a dielectric layer of the substrate or wafer 280 (the dielectric layer may be at least partially disposed on a metal layer of the substrate or wafer 280). The metal layer may comprise, for example, an aluminum or tungsten-based metal nitride. The dielectric layer may comprise silicon oxynitride or some other dielectric material. Typically, the substrate or wafer 280 has just completed an etching process wherein the underlying metal or dielectric layer has been patterned using the resist layer as a mask.

In step 110, a process gases containing one or more chemical species 284 is introduced under pressure into the plasma process chamber 200, via the gas inlet 240 and inlet nozzle 230. The one or more chemical species are ionized by the electric field generated within the chamber. In some embodiments, the one or more chemical species may comprise H₂O, argon (Ar), helium (He), and fluorine (F) based species and combinations thereof. Of these species, the H₂O and F based species comprise reactive species. The Ar and He are non-reactive species. No O₂ and/or N₂ species is/are used in the pure H₂O plasma to avoid charge accumulation (thus “pure” refers to the absence of O₂ and/or N₂ in the H₂O plasma). The pressure (partial pressure) exerted by the process gas inside the plasma process chamber 200 before initiating a plasma is adjusted to a value ranging between about 70 percent and 100 percent of the total pressure exerted by the gas 284.

In step 120, an electric field is generated inside the chamber 200 by the electric field generating means. In one embodiment, the electric field used to excite the plasma may be in the microwave or RF frequency range and the power of such a field may range between about 100 watts and about 10,000 watts.

In step 130, free electrons are discharged inside the plasma process chamber 200 and travel through the process gas to generate a pure H₂O plasma 290 in the chamber 200. As the H₂O plasma stabilizes, the pressure exerted by the gas 284 inside the plasma process chamber 200 is adjusted to be between about 0.1 Torr and 10 Torr. As schematically depicted in FIG. 4, the H₂O plasma 290 removes or strips the resist layer(s) 282 from the substrate or wafer 280 without substantially accumulating charges on the substrate or wafer 280.

FIGS. 5A-5C are surface charging maps of bare silicon wafers (no resist coating) after resist strip processing using a prior art O₂ plasma method and the pure H₂O plasma method. The surface charging maps compare the decharging ability of the prior art O₂ plasma method to the decharging ability of the pure H₂O plasma method. FIG. 5A is a surface charging map of a first wafer after performing the prior art O₂ plasma resist strip method for about 80 seconds, at a chamber temperature of about 245° C., a chamber pressure of about 2 Torr and an RF power of about 1400 watts, using a first prior art O₂ plasma recipe comprising an O₂ flow rate of about 3000 sccm (standard cubic centimeters per minute), an N₂ flow rate of about 200 sccm and a H₂O flow rate of about 500 sccm. The first wafer had a mean surface charging of 8.18 volts with a standard deviation of 0.17 volts. FIG. 5B is a surface charging map of a second wafer after performing the prior art O₂ plasma resist strip method for about 120 minutes, at a chamber temperature of about 80° C., a chamber pressure of about 800 m-Torr and an RF power of about 500 watts, using a second prior art O₂ plasma recipe comprising an O₂ flow rate of about 500 sccm. The second wafer had a mean surface charging of 14.1 volts with a standard deviation of 7.77 volts. FIG. 5C is a surface charging map of a third wafer after performing the pure H₂O plasma resist strip method for about 130 seconds, at a chamber temperature of about 245° C., a chamber pressure of about 2 Torr and an RF power of about 1400 watts, using a pure H₂O plasma recipe comprising a H₂O flow rate of about 500 sccm. The third wafer had a mean surface charging of 0.328 volts with a standard deviation of 0.058 volts.

FIGS. 6A and 6B are optical microscope (OM) photographs that show metal pads formed on wafers after performing a resist strip with a prior art O₂ plasma method. As can be seen, the metal pads suffered severe pad pitting using the O₂ plasma resist strip method.

FIGS. 7A and 7B are OM photographs that show metal pads formed on wafers after performing a resist strip with the pure H₂O plasma method. As can be seen, the metal pads had virtually no pad pitting using the H₂O plasma resist strip method, which neutralizes and/or releases charges during resist stripping process.

After resist stripping, wafers of certain products have a queue time of about 20 minutes. Severe galvanic metal corrosion of the top metal has been found in the wafers of these products after resist stripping using prior art O₂ plasma methods. It is believed that the severity of the corrosion is due to cumulative positive charging that occurs with these products, which accelerates galvanic metal corrosion. The pure H₂O plasma method substantially solves this metal galvanic corrosion problem because it extends the corrosion window to about four (4) hours. This in turn, allows the queue window to be extended. It should be noted that when O₂ and/or N₂ species are added to a pure H₂O plasma recipe, the corrosion window is considerably reduced to about 20 minutes. It is believed that the addition of the O₂ and/or N₂ induces positive charging, which worsens the galvanic metal corrosion.

With the advent of sub-micron size technology, reduced overlap tolerance between the metal lines and metal (e.g., tungsten) filled vias evokes several technical difficulties. Charge induced corrosion (dredge) of the tungsten which plugs the vias is one of the problems. Replacing the O₂ plasma method with the pure H₂O plasma method in the stripping process substantially solves tungsten dredge problems. As depicted in prior art process flow of FIG. 8A, a supplemental H₂O baking process (without RF) is currently used to address the tungsten dredge problem. However, some charge residue remains on the wafer surface after the supplemental H₂O baking process. The use of the H₂O plasma method eliminates the need for the supplemental H₂O baking process as depicted in the process flow of FIG. 8B, and substantially removes the charge residue on the wafer surface.

In another embodiment, the pure H₂O plasma method may be used for releasing or removing charges from a surface or surfaces of a substrate or wafer that have accumulated during one or more IC fabrication processes (e.g., a plasma photo-resist strip, scrubber cleaning, and/or film deposition).

Referring collectively to FIGS. 10 and 11, wherein FIG. 10 depicts the process chamber of FIG. 2 as used in the pure H₂O plasma charge removal method and wherein FIG. 11, is a flowchart depicting an embodiment of the pure H₂O plasma charge removal method, the pure H₂O plasma method commences in step 300 with a substrate or wafer 480 mounted on the wafer platform 220 inside the plasma process chamber 200. Typically, the substrate or wafer 480 has just completed an IC fabrication process, wherein charges have accumulated on the surface of the substrate or wafer 480.

In step 310, a process gases containing one or more chemical species 284 is introduced under pressure into the plasma process chamber 200, via the gas inlet 240 and inlet nozzle 230. The one or more chemical species are ionized by the electric field generated within the chamber. As described in the previous embodiment, the one or more chemical species may comprise H₂O, Ar, He, and F based species and combinations thereof. No O₂ and/or N₂ species is/are used in the pure H₂O plasma to avoid charge accumulation. The pressure (partial pressure) exerted by the process gas inside the plasma process chamber 200 before initiating a plasma is adjusted to a value ranging between about 70 percent and 100 percent of the total pressure exerted by the gas 284.

In step 320, an electric field is generated inside the chamber 200 by the electric field generating means. In one embodiment, the electric field may be in the microwave frequency range and the power of such a field may range between about 100 watts and about 10,000 watts.

In step 330, free electrons are discharged inside the plasma process chamber 200 and travel through the process gas to generate a pure H₂O plasma 290 in the chamber 200. As the pure H₂O plasma stabilizes, the pressure exerted by the gas 284 inside the plasma process chamber 200 is adjusted to be between about 0.1 Torr and 10 Torr.

The pure H₂O plasma method has greater de-charging capability than supplemental prior art H₂O baking methods. This can be seen by referring to the surface charging maps shown in FIGS. 9A-9C. FIG. 9A is a typical surface charging map of a wafer before de-charging. The wafer, before de-charging, had a mean surface charging of 10.6 volts with a standard deviation of 0.176 volts. FIG. 9B is a surface charging map of a wafer after performing a supplemental prior art in-situ H₂O baking process on the wafer for about 50 seconds, at a chamber temperature of about 245° C., a chamber pressure of about 2 Torr and an RF power of about 0 watts. The wafer had a mean surface charging of 2.26 volts with a standard deviation of 0.154 volts after prior art de-charging. FIG. 9C is a surface charging map of a wafer after performing the pure H₂O plasma de-charging method on the wafer for about 130 seconds, at a chamber temperature of about 245° C., a chamber pressure of about 2 Torr and an RF power of about 1400 watts, using a pure H₂O plasma recipe comprising a H₂O flow rate of about 500 sccm. The wafer had a mean surface charging of 1.57 volts with a standard deviation of 0.214 volts after de-charging with the H₂O plasma.

FIG. 12A is a surface charging map of a bare silicon wafer after performing a wafer scrubbing cleaning process on the wafer, using, for example, a jet scrubber which uses a high pressure spray of de-ionized water to clean the wafer. The wafer in FIG. 12A had a mean surface charging of 12.000 volts with a standard deviation of 16.700 volts after the wafer scrubbing process. FIG. 12B is a surface charging map of the wafer of FIG. 12A after performing the pure H₂O plasma method for about 130 seconds, at a chamber temperature of about 245° C., a chamber pressure of about 2 Torr and an RF power of about 1400 watts, using a pure H₂O plasma recipe comprising a H₂O flow rate of about 500 sccm. As can be seen, the wafer exhibited a substantially reduced mean surface charging of 1.740 volts with a standard deviation of 0.419 volts after treatment with the pure H₂O plasma method.

FIG. 13A is a surface charging map of a bare silicon wafer after performing a film deposition process on the wafer. The wafer in FIG. 13A had a mean surface charging of 6.490 volts with a standard deviation of 4.770 volts after film deposition processing. FIG. 13B is a surface charging map of the wafer of FIG. 13A after performing the pure H₂O plasma method for about 130 seconds, at a chamber temperature of about 245° C., a chamber pressure of about 2 Torr and an RF power of about 1400 watts, using a pure H₂O plasma recipe comprising a H₂O flow rate of about 500 sccm. The pure H₂O plasma treated wafer had a substantially reduced mean surface charging of 0.643 volts with a standard deviation of 0.478 volts.

In yet another embodiment, a pure H₂O vapor method may be used for releasing or removing charges from a surface or surfaces of a substrate or wafer that have accumulated during one or more IC fabrication processes (e.g., a plasma photo-resist strip, scrubber cleaning, and/or film deposition). In some embodiments, the pure H₂O vapor may comprise H₂O based reactive species. No O₂ and/or N₂ species is/are used in the pure H₂O vapor to avoid charge accumulation (thus “pure” refers to the absence of O₂ and/or N₂ in the pure H₂O vapor).

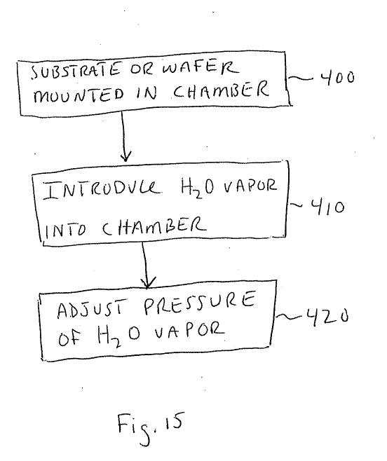

Referring collectively to FIGS. 14 and 15, wherein FIG. 14 depicts the process chamber of FIG. 2 as used in the pure H₂O vapor charge removal method and wherein FIG. 15, is a flowchart depicting an embodiment of the pure H₂O vapor charge removal method, the pure H₂O vapor method commences in step 400 with the substrate or wafer 580 mounted on the wafer platform 220 inside the plasma process chamber 200. As in the previous embodiment, the substrate or wafer 580 has typically just completed an IC fabrication process, wherein charges have accumulated on the surface of the substrate or wafer.

In step 410, a pure H₂O vapor 584 is introduced under pressure into the plasma process chamber 200, via the gas inlet 240 and inlet nozzle 230. The pure H₂O vapor is directed to the surface of the wafer under pressure. In one embodiment, the temperature of the pure H₂O vapor 584 entering the chamber 200 may be about 75-80 degrees C. The H₂O vapor 584 does not contain O₂ and/or N₂ species to avoid charge accumulation.

In step 420, as the pure H₂O vapor 584 fills the process chamber 200, the pressure exerted by the pure H₂O vapor 584 inside the plasma process chamber 200 is adjusted to a desired value. In one embodiment, the pressure exerted by the pure H₂O vapor 584 is adjusted to be about 100 Torr.

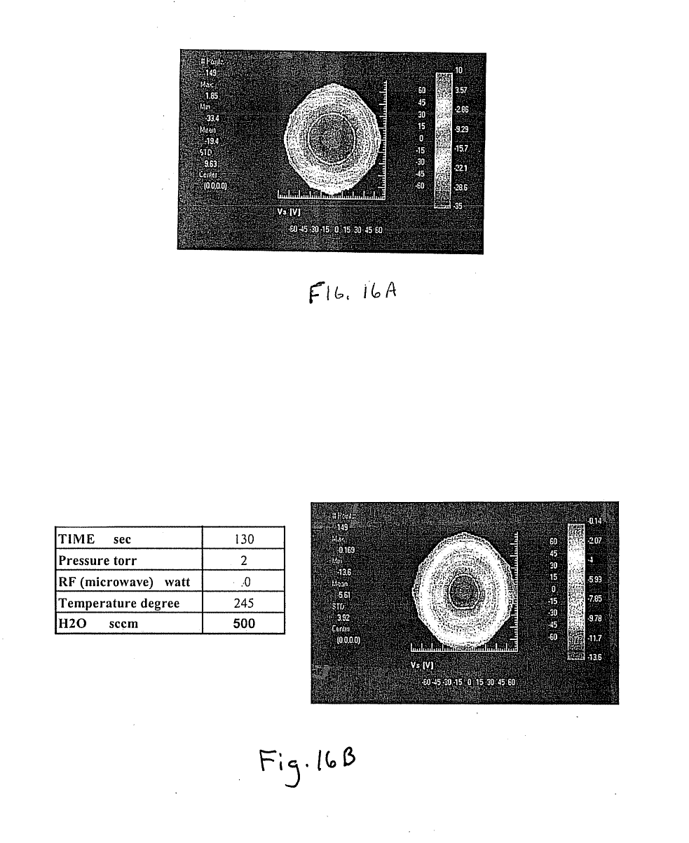

FIG. 16A is a surface charging map of a bare silicon wafer after performing a photo development process on the wafer. After photo development processing, the wafer had a mean surface charging of 19.400 volts with a standard deviation of 9.630 volts. FIG. 16B is a wafer surface charging map of the wafer of FIG. 16A after performing the pure H₂O vapor method for about 130 seconds, at a chamber temperature of about 245° C., a chamber pressure of about 2 Torr, using a pure H₂O vapor recipe comprising a pure H₂O vapor flow rate of about 500 sccm. As can be seen, the pure H₂O vapor method substantially reduced the wafer's mean surface charging to 5.610 volts with a standard deviation of 3.920 volts.

While the foregoing invention has been described with reference to the above, various modifications and changes can be made without departing from the spirit of the invention. Accordingly, all such modifications and changes are considered to be within the scope of the appended claims.

What is claimed is:

1. A method of removing electrical charges accumulated on a substrate or wafer, the method comprising the steps of:
placing or leaving the substrate or wafer in a process chamber; and
generating a water plasma in the chamber.

2. The method according to claim 1, wherein the water plasma generating step comprises:
introducing a gas comprising a water reactive species into the process chamber; and
discharging free electrons in the process chamber to form the water plasma therein.

3. The method according to claim 2, wherein the water reactive species comprises a partial pressure of at least about 70 percent.

4. The method according to claim 2, further comprising the step of adjusting the pressure of the gas to a value between about 0.1 Torr and about 10 Torr.

5. The method according to claim 2, wherein the gas further comprises a non-reactive species.

6. The method according to claim 5, wherein the non-reactive species is selected from the group consisting of Ar, He, and any combinations thereof.

7. The method according to claim 6, wherein the gas further comprises a fluorine-based reactive species.

8. The method according to claim 2, wherein the gas further comprises a fluorine-based reactive species.

9. The method according to claim 1, wherein the substrate or wafer is composed of a semiconductor material.

10. The method according to claim 1, wherein the electrical charges accumulated on the substrate or wafer result from a previously performed integrated circuit fabrication process.

11. A method of removing electrical charges accumulated on a substrate or wafer, the method comprising the steps of:
placing or leaving the substrate or wafer in a process chamber; and
introducing a water vapor into the chamber.

12. The method according to claim 11, further comprising the step of adjusting the pressure of the water vapor to a value between about 2 Torr to about 100 Torr.

13. The method according to claim 11, wherein the substrate or wafer is comprises a semiconductor material.

14. The method according to claim 11, wherein the electrical charges accumulated on the substrate or wafer result from a previously performed integrated circuit fabrication process.
